(19) United States
(12) Patent Application Publication
(10) Pub. No.: US 2009/0027128 A1
(43) Pub. Date: Jan. 29, 2009

(54) VARIABLE GAIN AMPLIFIER

(75) Inventor: Kazuhisa Ishiguro, Gunma (JP)

Correspondence Address: CONNOLLY BOVE LODGE & HUTZ LLP, 1875 EYE STREET, N.W., SUITE 1100, WASHINGTON, DC, 20006, US

(73) Assignee: Niigata Seimitsu Co., Ltd., Jyoetsu-shi (JP)

(21) Appl. No.: 12/180,063

(22) Filed: Jul. 25, 2008

(30) Foreign Application Priority Data
Jul. 27, 2007 (JP) 2007-196056

(51) Int. Cl. H03G 3/00

(52) U.S. Cl. 330/278

(57) ABSTRACT

The present invention provides a variable gain amplifier including a plurality of initial-stage LNAs 1 to 4 connected parallel to one input terminal IN, a next-stage LNA 5 connected after the initial-stage LNAs 1 to 4 and a variable current source 20 that performs control such that a total value of initial-stage control currents IB1 to IB4 simultaneously flowing through the initial-stage LNAs 1 to 4 is kept constant and such that-next-stage control currents IB13 and IB24 of magnitude proportional to the initial-stage control currents IB1 to IB4 which are let flow through the initial-stage LNAs 1 to 4 are let flow through the next-stage LNA 5, wherein the necessity for causing an excessively large fixed current to flow through the next-stage LNA 5 is eliminated and the next-stage control currents IB13 and IB24 are reduced to a minimum necessary magnitude so that increases of useless current consumption can be suppressed.

### BACKGROUND OF THE INVENTION

1. Field of the Invention

The present invention relates to a variable gain amplifier and is particularly suitable for use in a variable gain amplifier with a plurality of amplifiers connected to increase its variable gain range.

2. Description of the Related Art

In general, wireless communication apparatuses such as radio receivers are provided with an AGC (Automatic Gain Control) circuit for adjusting the gain of a received signal. An RF (Radio Frequency)-AGC circuit provided at a high-frequency stage is intended to adjust the gain of a high-frequency signal (antenna input signal) received at an antenna and keep the level of the received signal constant. The RF-AGC can be realized by controlling the amount of attenuation at an antenna damping circuit and the gain of an LNA (Low Noise Amplifier) or the like.

Especially, a radio tuner mounted on a mobile station such as a vehicle-mounted system or a cellular phone is required to increase the variable gain width (dynamic range) of the LNA so as to support a wide range of reception power of mobile reception. When, for example, the reception power is small, a high gain and low noise characteristic are required. On the other hand, when the reception power is large, high linearity is also required which indicates that a relationship between the control voltage of AGC and the decibel gain thereby controlled becomes linear.

To satisfy these two requirements and acquire a wide dynamic range, a variable gain low-noise amplifier is proposed which is configured such that four cascode amplifiers are connected in parallel and these cascode amplifiers are consecutively switched and used according to reception power (e.g., see Non-Patent Document 1). The cascode amplifiers themselves have basically no feedback from output to input, and are therefore frequently used as LNAs.

Non-Patent Document 1: SHARP TECHNICAL JOURNAL 88, April 2004 issue “One-Segment Tuner for Terrestrial Digital Television Broadcasting for Portable Devices” (FIGS. 3 to 5)

The variable gain low-noise amplifier described in this Non-Patent Document 1 adopts a circuit format that four cascode amplifiers are consecutively switched by controlling base currents I1, I2, I3 and I4 which are let flow through the amplifiers. More specifically, the base currents flowing through the cascode amplifiers are made to consecutively change at appropriate rates of I4→I3 →I2→I1 as the control voltage increases and a total value of the base currents that flow simultaneously is made to be always kept constant.

For example, in FIG. 4 of Non-Patent Document 1, only the base current I4 flows in an area where the control voltage is less than 0.8 [V] and only one cascode amplifier operates. On the other hand, in an area where the control voltage is equal to or more than 0.8 [V] and less than 1.2 [V], two base currents I4 and I3 flow at appropriate rates and two cascode amplifiers operate. The output currents of the two operating cascode amplifiers are converted to voltages using resistive load and the respective voltages are added up and outputted as an amplified signal.

The variable gain low-noise amplifier of above Non-Patent Document 1 is constructed through a Bi-CMOS (Bipolar Complementary Metal Oxide Semiconductor) process. Using this Bi-CMOS process, an LNA having a voltage gain on the order of 20 [dB], noise factor on the order of 3 [dB] can be realized with one cascode amplifier. Furthermore, since the output stage of the cascode amplifier is resistive load, connecting output points of a plurality of cascode amplifiers allows the output voltages of the respective cascode amplifiers to be added up.

On the other hand, to meet the recent demands for the speed enhancement, miniaturization and reduction of power consumption of transistors, it is preferable to construct a variable gain amplifier having a characteristic equivalent or superior to that of the amplifier in Non-Patent Document 1 using semiconductor miniaturized through a CMOS process. In this case, it is difficult to realize an LNA having a voltage gain of 20 [dB] or more and noise factor of 3 [dB] or less using a single cascode amplifier. Therefore, a technique of connecting a plurality of cascode amplifiers in a multi-stage mode is adopted.

However, when general resistive load cascode amplifiers as described in Non-Patent Document 1 are used, it is difficult to reduce the noise factor (NF) through a CMOS process and a desired NF cannot be obtained, resulting in a problem that reception sensitivity deteriorates. Therefore, using noise cancellation type cascode amplifiers instead of general cascode amplifiers can reduce the NF even through the CMOS process.

However, since the noise cancellation type cascode amplifier has a source-follower type output stage, output signals of the respective cascode amplifiers cannot be added up at the outputs like the resistive load cascode amplifiers. Therefore, it is not possible to acquire a wide dynamic range while improving the NF by simply connecting in parallel a plurality of cascode amplifiers configured through a CMOS process and exerting current control.

Therefore, the present applicant has invented a variable gain amplifier intended to acquire a wide dynamic range through a CMOS process and to satisfy a good noise factor and applied for a patent (e.g., see Patent Document 1). The invention described in this Patent Document 1 is configured by including a plurality of initial-stage amplifiers, a next-stage amplifier connected after the plurality of initial-stage amplifiers and a variable current source that controls control currents flowing through the plurality of initial-stage amplifiers so that a total value of simultaneously flowing control currents is kept constant.

Patent Document 1: Japanese Patent Application No. 2007-163695

### SUMMARY OF THE INVENTION

However, the invention according to above Patent Document 1 requires the next-stage amplifier in addition to the parallel connected initial-stage amplifiers. This results in a problem that the total current consumption increases by the amount corresponding to the next-stage amplifiers.

The present invention has been implemented to solve such a problem and it is an object of the present invention to provide a variable gain amplifier capable of satisfying a wide dynamic range and a good noise factor through a CMOS process and at the same time suppressing increases in current consumption to a minimum.

In order to solve the above described problem, the variable gain amplifier of the present invention includes a plurality of initial-stage amplifiers that perform amplification operation by initial-stage control currents, a next-stage amplifier that performs amplification operation by a next-stage control current and a variable current source that controls the initial-stage control currents and the next-stage control current, wherein output lines of the initial-stage amplifiers through which initial-stage control currents never flow simultaneously are connected with each other to form a plurality of combined output lines, the plurality of combined output lines are connected to a plurality of input ends of the next-stage amplifier separately. The next-stage amplifier amplifies the signals inputted from the plurality of input ends respectively, adds up the amplified signals and outputs the resulting signal. Furthermore, the variable current source performs control such that the total value of the initial-stage control currents which are let flow through the simultaneously operated initial-stage amplifiers out of the plurality of initial-stage amplifiers is kept constant and such that a next-stage control current of magnitude proportional to the initial-stage control currents which are let flow through the initial-stage amplifiers is let flow through the next-stage amplifier.

According to the present invention configured as described above, even when the output stages of the transistors making up the initial-stage amplifiers are of a source-follower type, output lines of the initial-stage amplifiers through which the initial-stage control currents never flow simultaneously, that is, the initial-stage amplifiers that never operate simultaneously are connected together, and therefore signals are never added up on the connected combined output lines. The output signals of the simultaneously operating initial-stage amplifiers are added up by the next-stage amplifier to which the output signals are inputted through the plurality of combined output lines separately. This allows even the CMOS process variable gain amplifier to acquire a wide dynamic range. Furthermore, since the total value of the initial-stage control currents which are let flow through the plurality of initial-stage amplifiers is controlled so as to be always kept constant, it is also possible to acquire a low noise characteristic and high linearity in a relationship between the control voltage and gain. Moreover, according to the present invention, since the next-stage control current flowing through the next-stage amplifier is controlled to the magnitude proportional to the initial-stage control currents, an excessively large fixed current need not be let flow through the next-stage amplifier, making it possible to suppress increases of useless current consumption.

### BRIEF DESCRIPTION OF THE DRAWINGS

FIG. 1 shows a configuration example of a variable gain amplifier according to this embodiment;

FIG. 2 shows an example of initial-stage control currents flowing through four initial-stage LNAs;

FIG. 3 shows an example of next-stage control currents flowing through a next-stage LNA;

FIG. 4 is a circuit diagram showing a configuration example of the initial-stage LNA according to this embodiment;

FIG. 5 is a circuit diagram showing a configuration example of the next-stage LNA according to this embodiment; and

FIG. 6 is a circuit diagram showing a configuration example of the variable current source according to this embodiment.

### DETAILED DESCRIPTION OF THE PREFERRED EMBODIMENTS

Hereinafter, an embodiment of the present invention will be explained with reference to the accompanying drawings. FIG. 1 shows a configuration example of a variable gain amplifier according to this embodiment. As shown in FIG. 1, the variable gain amplifier of this embodiment is constructed of four initial-stage LNAs 1 to 4, one next-stage LNA 5, three attenuators 11 to 13 and a variable current source 20. All these components are integrated into one IC chip through a CMOS process.

The four initial-stage LNAs 1 to 4 correspond to the plurality of initial-stage amplifiers in the present invention. These four initial-stage LNAs 1 to 4 are connected parallel to one input terminal IN and amplify signals inputted to the initial-stage amplifiers 1 to 4 by initial-stage control currents IB1 to IB4 which are let flow through the respective LNAs from the variable current source 20.

The three attenuators 11 to 13 correspond to level adjusters of the present invention. These three attenuators 11 to 13 are connected parallel to the one input terminal IN and connected to the input sides of the second to fourth initial-stage amplifiers 2 to 4 out of the four initial-stage amplifiers 1 to 4. The three attenuators 11 to 13 are intended to adjust the level of a signal inputted from the one input terminal IN so that the levels of the signals inputted to the four initial-stage LNAs 1 to 4 are different from each other.

More specifically, the attenuators 11 to 13 attenuate the signal inputted from the one input terminal IN. The amounts of attenuation of the attenuators 11 to 13 are different from each other and are set so as to increase in order of the first attenuator 11<second attenuator 12<third attenuator 13. When, for example, the variable gain ranges of the four initial-stage LNAs 1 to 4 are on the order of 20 [dB] respectively, it is possible to set the amount of attenuation of the first attenuator 11 to 20 [dB], the amount of attenuation of the second attenuator 12 to 40 [dB] and the amount of attenuation of the third attenuator 13 to 60 [dB].

In this case, the first initial-stage LNA 1 amplifies the signal inputted from the one input terminal IN. The second initial-stage LNA 2 amplifies the signal inputted from the one input terminal IN and attenuated by 20 [dB] at the first attenuator 11. The third initial-stage LNA 3 amplifies the signal inputted from the one input terminal IN and attenuated by 40 [dB] at the second attenuator 12. Furthermore, the fourth initial-stage LNA 4 amplifies the signal inputted from the one input terminal IN and attenuated by 60 [dB] at the third attenuator 13.

Here, the case where the three attenuators 11 to 13 are connected parallel to the one input terminal IN has been explained but the present invention is not limited to this. For example, three attenuators 11 to 13 may be cascaded in three stages to the one input terminal IN, signals may be extracted from output taps of the attenuators 11 to 13 of the respective stages and inputted to the second to fourth initial-stage LNAs 2 to 4 respectively. In this case, if, for example, the amounts of attenuation of the attenuators 11 to 13 are set to 20 [dB], a signal attenuated by 20 [dB] is extracted from the output tap of the first attenuator 11, a signal attenuated in two stages by a total of 40 [dB] is extracted from the output tap of the second attenuator 12 and a signal attenuated in three stages by a total of 60 [dB] is extracted from the output tap of the third attenuator 13.

Here, the configuration where the attenuators 11 to 13 are connected to the initial-stage LNAs 2 to 4 out of the four initial-stage LNAs 1 to 4 has been explained, but the present invention is not limited to this. For example, the attenuators may be connected to all the initial-stage LNAs 1 to 4.

The next-stage LNA 5 corresponds to the next-stage amplifier of the present invention, is connected after the four initial-stage LNAs 1 to 4 and amplifies the signal inputted to the next-stage LNA 5 by next-stage control currents IB13 and IB24 which are let flow from the variable current source 20. Here, the output lines of the initial-stage LNAs through which the initial-stage control currents IB1 to IB4 do not flow simultaneously out of the four initial-stage LNAs 1 to 4 are connected together to form a plurality of combined output lines L1 and L2. The plurality of combined output lines L1 and L2 are connected to the plurality of input terminals IN1 and IN2 of the next-stage LNA 5 separately.

In the example of FIG. 1, the output lines of the initial-stage LNA 1 and third initial-stage LNA 3 are connected together to form the first combined output line L1, and the output lines of the second initial-stage LNA 2 and fourth initial-stage LNA 4 are connected together to form the second combined output line L2. The two combined output lines L1 and L2 are then connected to the plurality of input terminals IN1 and IN2 of the next-stage LNA 5 separately. The next-stage LNA 5 amplifies the signals inputted from the two input terminals IN1 and IN2, adds up the amplified signals and outputs the resulting signal.

The variable current source 20 inputs a control voltage VAGC for gain adjustment from an AGC circuit (not shown) and generates the initial-stage control currents IB1 to IB4 to be let flow through the four initial-stage LNAs 1 to 4 and the next-stage control currents IB13 and IB24 to be let flow through the one next-stage LNA 5 based on the control voltage VAGC. At this moment, the variable current source 20 performs control so that the total value of the initial-stage control currents IB1 to IB4 flowing through the four initial-stage LNAs 1 to 4 is always kept constant regardless of the magnitude of the control voltage VAGC. Furthermore, the variable current source 20 also performs control so that the next-stage control currents IB13 and IB24 flowing through the next-stage LNA 5 have magnitude proportional to the initial-stage control currents IB1 to IB4 flowing through the initial-stage LNAs 1 to 4.

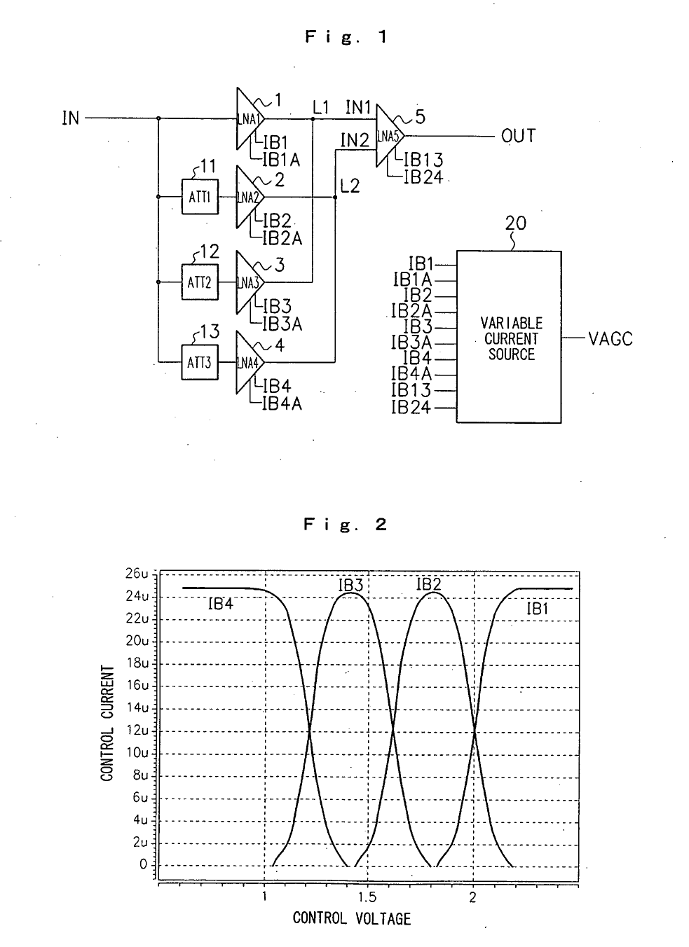

FIG. 2 shows an example of the initial-stage control currents IB1 to IB4 flowing through the four initial-stage LNAs 1 to 4. As is evident from FIG. 2, only the fourth initial-stage control current IB4 flows in an area where the control voltage VAGC is less than approximately 1.05 [V] and only the fourth initial-stage LNA 4 operates. Furthermore, the fourth initial-stage control current IB4 and third initial-stage control current IB3 flow at appropriate rates in an area where the control voltage VAGC is approximately 1.05 [V] or more and less than approximately 1.4 [V] and the fourth initial-stage LNA 4 and third initial-stage LNA 3 operate. Furthermore, only the third initial-stage control current IB3 flows in an area where the control voltage VAGC is approximately 1.4 [V] or more and less than approximately 1.45 [V] and only the third initial-stage LNA 3 operates.

In this way, depending on the value of the control voltage VAGC, there is an area where the fourth initial-stage control current IB4 and the third initial-stage control current IB3 flow simultaneously. Similarly, there are an area where the third initial-stage control current IB3 and the second initial-stage control current IB2 flow simultaneously and an area where the second initial-stage control current IB2 and the first initial-stage control current IB1 flow simultaneously. On the other hand, the fourth initial-stage control current IB4 and first initial-stage control current IB1 or second initial-stage control current IB2 never flow simultaneously and the third initial-stage control current IB3 and the first initial-stage control current IB1 never flow simultaneously.

Here, the variable current source 20 performs control such that the amount of current when the first to fourth initial-stage control currents IB1 to IB4 flow singly, the total amount of current when the fourth initial-stage control current IB4 and the third initial-stage control current IB3 flow simultaneously, the total amount of current when the third initial-stage control current IB3 and the second initial-stage control current IB2 flow simultaneously and the total amount of current when the second initial-stage control current IB2 and the first initial-stage control current IB1 flow simultaneously are always kept constant no matter what control voltage VAGC is supplied.

As described so far, the signal inputted from the one input terminal IN and signals resulting from attenuating that signal in increments of 20 [dB] through the three attenuators 11 to 13 are amplified by the four initial-stage LNAs 1 to 4 and the initial-stage control currents IB1 to IB4 which are let flow through the respective initial-stage LNAs 1 to 4 are controlled so that the amplifications by the initial-stage LNAs 1 to 4 are switched consecutively. More specifically, control is performed such that as the control voltage VAGC increases, the initial-stage control currents IB1 to IB4 flowing through the initial-stage LNAs 1 to 4 change consecutively at appropriate rates in order of IB4→IB3 →IB2→IB1.

By so doing, it is possible to acquire a wide dynamic range on the order of 80 [dB] of the four initial-stage LNAs 1 to 4 as a whole compared to the dynamic range where only the order of 20 [dB] could be acquired by the individual initial-stage LNAs 1 to 4. Furthermore, keeping the total value of the initial-stage control currents IB1 to IB4 flowing through the four initial-stage LNAs 1 to 4 simultaneously always constant also allows a low noise characteristic and high linearity to be acquired.

Furthermore, when some of the initial-stage control currents IB1 to IB4 are not let flow through some of the initial-stage LNAs 1 to 4, the variable current source 20 generates OFF currents IB1A to IB4A indicating that fact and outputs the OFF currents to the initial-stage LNAs 1 to 4. More specifically, the variable current source 20 generates the first OFF current IB1A when the first initial-stage control current IB1 is not let flow through the first initial-stage LNA 1 and generates the second OFF current IB2A when the second initial-stage control current IB2 is not let flow through the second initial-stage LNA 2. Furthermore, the variable current source 20 generates the third OFF current IB3A when the third initial-stage control current IB3 is not let flow through the third initial-stage LNA 3 and generates the fourth OFF current IB4A when the fourth initial-stage control current IB4 is not let flow through the fourth initial-stage LNA 4.

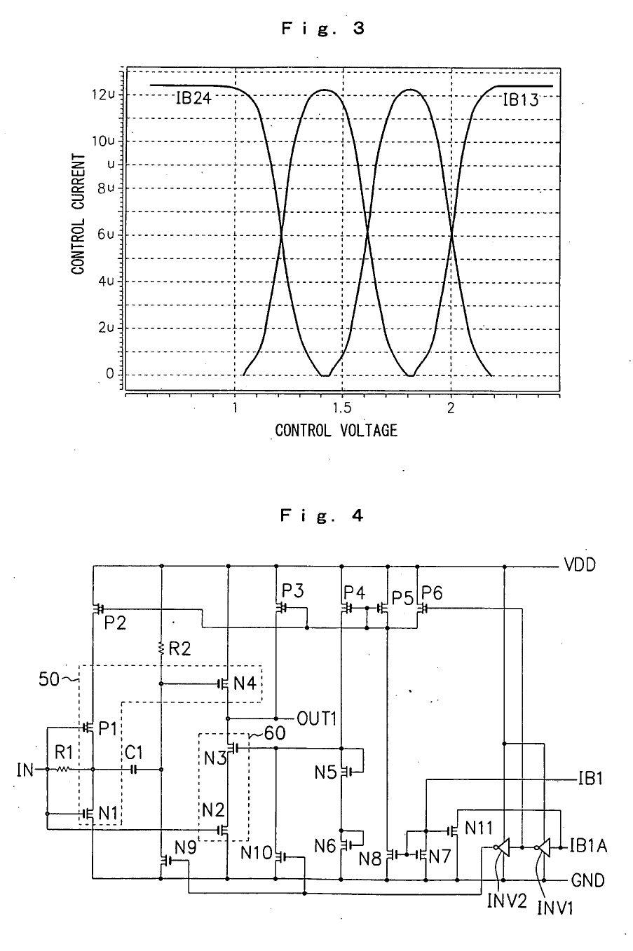

FIG. 3 shows an example of the next-stage control currents IB13 and IB24 flowing through the next-stage LNA 5. As is evident from a comparison between FIG. 2 and FIG. 3, the variable current source 20 performs control such that the next-stage control currents IB13 and IB24 of magnitude proportional to the initial-stage control currents IB1 to IB4 flowing through the initial-stage LNAs 1 to 4 are let flow through the next-stage LNA 5.

Here, the first next-stage control current IB13 is used to amplify the signal inputted from one input terminal IN1 through the first combined output line L1 formed by connecting the output lines of the first initial-stage LNA 1 and the third initial-stage LNA 3. This first next-stage control current IB13 has the magnitude proportional to the first initial-stage control current IB1 and third initial-stage control current IB3.

On the other hand, the second next-stage control current IB24 is used to amplify the signal inputted from the other input terminal IN2 through the second combined output line L2 formed by connecting the output lines of the second initial-stage LNA 2 and the fourth initial-stage LNA 4. This second next-stage control current IB24 has the magnitude proportional to the second initial-stage control current IB2 and fourth initial-stage control current IB4.

As described above, the next-stage LNA 5 amplifies the signals inputted from the two input terminals IN1 and IN2, adds up the respective amplified signals and outputs the resulting signal. In this way, the next-stage LNA 5 finally adds up the two signals, and thereby performs control such that the next-stage control currents IB13 and IB24 used for amplification operation before the addition have magnitude ½ of the initial-stage control currents IB1 to IB4.

Next, the circuit configuration of the initial-stage LNAs 1 to 4 according to this embodiment will be explained. Since all the initial-stage LNAs 1 to 4 have similar circuit configurations, the configuration of the first initial-stage LNA 1 will be explained as a representative below. FIG. 4 is a circuit diagram showing a configuration example of the first initial-stage LNA 1.

In FIG. 4, a pMOS transistor P1 and nMOS transistor N1 connected to the input terminal IN make up an inverting amplifier. The inverting amplifier P1 and N1 amplifies a signal inputted from the input terminal IN by inverting the phase of the signal. The amplified signal is outputted to a second-stage via a coupling capacitor C1. An nMOS transistor N4 connected to the next-stage of the coupling capacitor C1 is a source-follower type buffer amplifier. These inverting amplifier P1 and N1 and buffer amplifier N4 make up a first amplifier 50 of the present invention.

nMOS transistors N2 and N3 connected parallel to the inverting amplifier P1 and N1 with respect to the input terminal IN are cascode amplifiers and correspond to a second amplifier 60 of the present invention. The nMOS transistor N2 which corresponds to a pre-stage of the cascode connection is a source-grounded amplifier and the nMOS transistor N3 which corresponds to a post-stage of the cascode connection is a gate-grounded amplifier. This second amplifier 60 amplifies the signal inputted from the input terminal IN. nMOS transistors N5 and N6 is bias circuit to give a gate-grounded bias to the transistor N3 which corresponds to a post-stage of the cascode connection of the second amplifier 60.

Here, the output (source of the transistor N4) of the first amplifier 50 is connected to the output (drain of the transistor N3) of the second amplifier 60 and the connected line is connected to an output terminal OUT1 of the first initial-stage LNA 1. As for the first amplifier 50, the input signal is amplified with opposite phases by the inverting amplifier P1 and N1 and the amplified signal is outputted with the same phase (with no amplification) to the output terminal OUT1 by the source-follower of the buffer amplifier N4. Therefore, the signal outputted to the output terminal OUT1 has a phase opposite to that of the input signal. On the other hand, as for the second amplifier 60, the input signal is amplified with opposite phase by the source-grounded amplifier N2, the amplified signal is outputted with the same phase (no amplification) to the output terminal OUT1 via the gate-grounded amplifier N3. For this reason, the signal outputted to the output terminal OUT1 has a phase opposite to that of the input signal. In this way, the signal amplified by the first amplifier 50 and the signal amplified by the second amplifier 60 have the same phase at the output terminal OUT1 of the initial-stage LNA 1 and never cancel outreach other.

On the other hand, noise generated at the sources and drains of the inverting amplifier P1 and N1 are outputted with the same phase (no amplification) to the output terminal OUT1 of the initial-stage LNA 1 via the coupling capacitor C1 and buffer amplifier N4. On the other hand, noise which is voltage-divided (attenuated) by a resistor R1 and a signal source resistor (not shown) and outputted with the same phase to the input terminal IN is amplified with opposite phase by the source-grounded amplifier N2. Therefore, the phase of the noise generated at the inverting amplifier P1 and N1 and outputted to the output terminal OUT1 via the buffer amplifier N4 is opposite to the phase of the noise outputted to the output terminal OUT1 via the second amplifier 60, and therefore the noise generated at the inverting amplifier P1 and N1 can be canceled at the output terminal OUT1. Therefore, this amplifier produces less noise than the conventional cascode amplifier made up of simply cascode-connected bipolar transistors. nMOS transistors N7 and N8 form a current mirror circuit and the initial-stage control current IB1 is inputted to the drain of one transistor N7 side as a reference current so that the same initial-stage control current IB1 is also let flow through the drain on the other transistor N8 side. Furthermore, pMOS transistors P2 to P5 also make up a current mirror circuit and the initial-stage control current IB1 outputted from the nMOS transistor N8 is inputted to the drain of one transistor P5 side as a reference current so that a current proportional to the initial-stage control current IB1 flows through the drain on the other transistors P2 to P4.

In this way, a current proportional to the initial-stage control current IB1 is supplied to the first amolifier 50, second amplifier 60 and bias circuit N5 and N6 through a combination of the two current mirror circuits N7 and N8, and P2 to P5. That is, the initial-stage control current IB1 inputted from the variable current source 20 flows through the two current mirror circuits N7 and N8, and P2 to P5, and a current proportional to the initial-stage control current IB1 is supplied to the first amplifier 50, second amplifier 60 and bias circuit N5 and N6. In this way, the gain of the initial-stage LNA 1 is controlled by the initial-stage control current IB1.

Inverters INV1 and INV2, pMOS transistor P6 and nMOS transistors N9 and N10 make up switch means of the present invention. This switch means is intended to completely turn OFF the operations of the first amplifier 50 and second amplifier 60 when the initial-stage control current IB1 is not supplied from the variable current source 20.

The two inverters INV1 and INV2 are cascaded and an OFF current IB1A is inputted to the pre-stage inverter INV1. The output end of the pre-stage inverter INV1 is connected to the gate of the pMOS transistor P6. The drain of this pMOS transistor P6 is connected to the gates of the pMOS transistors P2 to P5 which make up a current mirror circuit. The sources of the pMOS transistors P2 to P6 are connected to a supply voltage VDD.

On the other hand, the output end of the post-stage inverter INV2 is connected to the gates of the nMOS transistors N9 and N10. The drain of the nMOS transistor N9 is connected to the gate of the transistor N4 which makes up the first amplifier 50 and the drain of the nMOS transistor N10 is connected to the gate of the transistor N3 which makes up the second amplifier 60. Furthermore, the sources of the nMOS transistors N9 and N10 are grounded.

Furthermore, the input end of the pre-stage inverter INV1 is connected to the drain of an nMOS transistor N11. The gate of the nMOS transistor N11 is connected to the input ends (input end of the initial-stage control current IB1) of the current mirror circuit N7 and N8 and the source is grounded.

Here, the operation of the switch means configured as shown above will be explained. When the initial-stage control current IB1 is not supplied from the variable current source 20 (initial-stage control current IB1 is low level), the OFF current IB1A is supplied from the variable current source 20. The OFF current IB1A whose phase has been inverted by the pre-stage inverter INV1 is supplied to the gate of the pMOS transistor P6. In this case, the output end of the pre-stage inverter INV1 becomes low level and the pMOS transistor P6 turns ON.

Thus, a high level signal outputted from the drain of the pMOS transistor P6 is supplied to the gates of the PMOS transistors P2 to P5 which make up the current mirror circuit. Therefore, all the pMOS transistors P2 to P5 turn OFF. When the pMOS transistors P2 to P5 turn OFF, the first amplifier 50 (inverting amplifier P1 and N1), second amplifier 60 and bias circuit N5 and N6 can be completely separated from the supply voltage VDD.

On the other hand, the OFF current IB1A whose phase has been restored to its original phase by the post-stage inverter INV2 is supplied to the gates of the nMOS transistors N9 and N10. Thus, a high level signal outputted from the inverter INV2 is supplied to the gates of the nMOS transistors N9 and N10. Therefore, both the nMOS transistors N9 and N10 turn ON. Therefore, the transistors N3 and N4 completely turn OFF because their gates become low level.

As described above, when the initial-stage control current IB1 is not supplied from the variable current source 20, the first amplifier 50, second amplifier 60 and bias circuit N5 and N6 are completely separated from the supply voltage VDD. Furthermore, both the transistor N4 making up the first amplifier 50 and the transistor N3 making up the second amplifier 60 completely turn OFF. This allows the operations of the first amplifier 50 and second amplifier 60 to be completely turned OFF.

When the initial-stage control current IB1 is supplied from the variable current source 20 to the initial-stage LNA 1, the nMOS transistor N11 turns ON and the OFF current IB1A is pulled into the ground GND through the nMOS transistor N11.

Next, the circuit configuration of the next-stage LNA 5 according to this embodiment will be explained. FIG. 5 is a circuit diagram showing a configuration example of the next-stage LNA 5. In FIG. 5, C21 and C22 are coupling capacitors connected to two combined output lines L1 and L2. Cascode amplifiers are connected to these two coupling capacitors C21 and C21 respectively.

A cascode amplifier connected to the first combined output line L1 via the coupling capacitor C21 is constructed of two cascoded nMOS transistors N21 and N23. Furthermore, a cascode amplifier connected to the second combined output line L2 via the coupling capacitor C22 is constructed of two cascoded nMOS transistors N22 and N23.

The nMOS transistor N23 serves as both the next-stage amplifier of the cascode amplifier that amplifies the signal supplied from the first combined output line L1 and the next-stage amplifier of the cascode amplifier that amplifies the signal supplied from the second combined output line L2. A load resistor RL is connected to the drain side of this nMOS transistor N23, that is, the output stage of the cascode amplifier (output terminal OUT side of the next-stage LNA 5).

That is, the next-stage LNA 5 is configured to amplify the signal supplied from the first combined output line L1 via the one input terminal IN1 and the signal supplied from the second combined output line L2 via the other input terminal IN2 through the two cascode amplifiers respectively, add up the respective amplified signals and output the resulting signal from the output terminal OUT. nMOS transistors N24 and N25 are transistors to give a bias for gate grounding to the nMOS transistor N23 which corresponds to the post-stage side of cascode connection. An nMOS transistor N26 is one of transistors making up a current mirror circuit and makes up a current mirror circuit together with the nMOS-transistor N21 which corresponds to the first stage of the cascode amplifier N21 and N23. Furthermore, an nMOS transistor N27 is one of transistors making up a current mirror circuit and makes up a current mirror circuit together with the nMOS transistor N22 which corresponds to the first stage of the cascoded amplifier N22 and N23.

That is, the first next-stage control current IB13 is inputted to the drain of the nMOS transistor N26 as a reference current so that a current proportional to the first next-stage control current IB13 flows through the drain of the nMOS transistor N21 which corresponds to the pre-stage side of the cascode amplifier N21 and N23. That is, the current proportional to the first next-stage control current IB13 inputted from the variable current source 20 to the nMOS transistor N26 is supplied to the cascode amplifier N21 and N23 which are current-mirror-connected to the nMOS transistor N26. Thus, the gain of the cascode amplifier N21 and N23 making up the next-stage LNA 5 are controlled by the first next-stage control current IB13.

Furthermore, the second next-stage control current IB24 is inputted to the drain of the nMOS transistor N27 as a reference current so that a current proportional to the second next-stage control current IB24 flows through the drain of the nMOS transistor N22 which corresponds to the pre-stage side of the cascode amplifier N22 and N23. That is, the current proportional to the second next-stage control current IB24 inputted from the variable current source 20 to the nMOS transistor N27 is supplied to the cascode amplifier N22 and N23 which are current-mirror-connected to the nMOS transistor N27. Thus, the gain of the cascode amplifier N22 and N23 making up the next-stage LNA 5 are controlled by the second next-stage control current IB24.

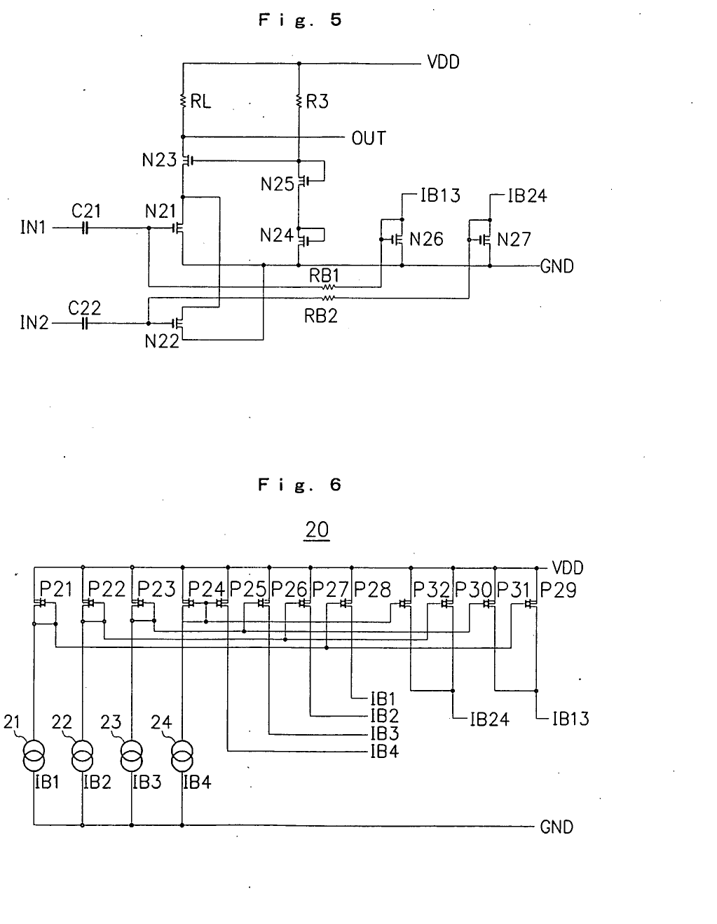

Next, the circuit configuration of the variable current source 20 according to this embodiment will be explained. FIG. 6 is a circuit diagram showing a configuration example of the variable current source 20. In FIG. 6, reference numerals 21 to 24 denote constant-current circuits, which generate constant currents of the same magnitudes as those of the initial-stage control currents IB1 to IB4. These four constant-current circuits 21 to 24 are connected to the drains of four pMOS transistors P21 to P24.

The above four pMOS transistors P21 to P24 and other four pMOS transistors P25 to P28 make up four sets of current mirror circuits. The one PMOS transistors P21 to P24 making up the current mirror circuit and the other pMOS transistors P25 to P28 are designed to have a transistor area ratio of 1:1.

This causes the currents IB1 to IB4 generated at the constant-current circuits 21 to 24 to flow through the drains of the one pMOS transistors P21 to P24 as reference currents and causes the same currents IB1 to IB4 to also flow through the drains of the other current-mirror-connected PMOS transistors P25 to P28. The variable current source 20 supplies the currents flowing through the drains of these pMOS transistors P25 to P28 to the initial-stage LNAs 1 to 4 as the initial-stage control currents IB1 to IB4.

Furthermore, the above four PMOS transistors P21 to P24 and further four pMOS transistors P29 to P32 make up four sets of current mirror circuits. The one pMOS transistors P21 to P24 making up the current mirror circuit and the other pMOS transistors P29 to P32 are designed to have a transistor area ratio of 2:1 respectively. This causes the currents IB1 to IB4 generated at the constant-current circuits 21 to 24 to flow through the drains of the one pMOS transistors P21 to P24 as reference currents and causes currents of magnitude half the currents IB1 to IB4 to flow through the drains of the other current-mirror-connected pMOS transistors P29 to P32.

Here, the drains of the pMOS transistors P29 and P31 through which currents IB1/2 and IB3/2 flow are connected to each other. Thus, the currents flowing through the drains of the two pMOS transistors P29 and P31 are combined and supplied to the next-stage LNA 5 as the first next-stage control current IB13. Likewise, the drains of the pMOS transistors P30 and P32 through which currents IB2/2 and IB4/2 flow are connected to each other. Thus, the currents flowing through the drains of the two pMOS transistors P30 and P32 are combined and supplied to the next-stage LNA 5 as the second next-stage control current IB24.

As explained in detail so far, this embodiment adopts a 2-stage configuration of the initial-stage LNAs 1 to 4 and the next-stage LNA 5 and connects the output lines of the initial-stage LNAs 1 to 4 through which the initial-stage control currents IB1 to IB4 never flow simultaneously, that is, the initial-stage LNAs 1 to 4 that never operate simultaneously so that the combined output lines L1 and L2 are connected to the next-stage LNA 5 respectively. And the next-stage 5 adds up the output signals of the simultaneously operating initial-stage LNAs 1 to 4.

As the result, in even a CMOS process variable gain amplifier whose output stage constitutes a source follower, this allows the next-stage LNA 5 to add up output signals of the simultaneously operating initial-stage amplifiers 1 to 4, and can thereby acquire a wide dynamic range. Furthermore, since control is performed such that the total value of the initial-stage control currents IB1 to IB4 flowing through the plurality of initial-stage LNAs 1 to 4 is always kept constant, it is possible to acquire a low noise characteristic and high linearity in a relationship between a control voltage and gains.

Furthermore, according to this embodiment, noise produced at the inverting amplifier P1 and N1 of the initial-stage LNAs 1 to 4 and noise outputted from the second amplifier 60 connected parallel to the inverting amplifier P1 and N1 are added up with opposite phases and thereby cancel out each other. This suppresses deterioration of noise factors in the CMOS process initial-stage LNAs 1 to 4.

Furthermore, according to this embodiment, the switch means can completely turn OFF the operations of the first amplifier 50 and second amplifier 60 of the initial-stage LNAs 1 to 4 to which the initial-stage control currents IB1 to IB4 are not supplied. This prevents noise from occurring from the transistors of the initial-stage LNAs 1 to 4 which are not involved in the amplification operation, and can thereby suppress deterioration of noise factors at the CMOS process initial-stage LNAs 1 to 4.

The overall noise factor NF when amplifiers are cascaded is generally given by the following expression.

NF=NF1+(NF2−1)/G1+(NF3−1)/G1*G2+

Here, NF1 is a noise factor of the first-stage amplifier, NF2 is a noise factor of the second-stage amplifier and NF3 is a noise factor of the third-stage amplifier. Furthermore, G1 is a gain of the first-stage amplifier and G2 is a gain of the second-stage amplifier.

As is clear from the above expression, reducing the overall noise factor NF of the amplifier requires:

(1) a reduction of the noise factor NF1 of the first-stage amplifier

(2) an increase of the gain G1 of the first-stage amplifier.

According to this embodiment, it is especially necessary to reduce the noise factors of the initial-stage LNAs 1 to 4. Since this embodiment can reduce the noise factors of the initial-stage LNAs 1 to 4 as described above, the overall noise factor of the variable gain amplifier can be reduced and high reception sensitivity can be obtained.

Moreover, according to this embodiment, the variable current source 20 performs control so that the next-stage control currents IB13 and IB24 of magnitude proportional to the initial-stage control currents IB1 to IB4 flowing through the initial-stage LNAs 1 to 4 are let flow through the next-stage LNA 5. This eliminates the necessity for causing an excessively large fixed current to flow through the next-stage LNA 5, reduces the next-stage control currents IB13 and IB24 to a minimum necessary magnitude, and can thereby suppress increases of useless current consumption.

The above embodiment has assumed that the number of the initial-stage LNAs 1 to 4 is four, but this is only an example. Furthermore, the above embodiment connects the outputs of the two initial-stage LNAs to form combined output lines, but this is also a mere example. That is, it is also possible to form combined output lines by connecting outputs of three or more initial-stage LNAs if these are the initial-stage LNAs through which control currents never flow simultaneously.

Furthermore, the above embodiment has explained an example where at most two initial-stage control currents out of the four initial-stage control currents IB1 to IB4 are let flow simultaneously, but the present invention is not limited to this. For example, in a case where the number of initial-stage LNAs is more than four, three or more initial-stage control currents may also be let flow simultaneously.

Furthermore, the variable gain amplifier in the above embodiment is suitable for use in an RF-AGC circuit of a radio tuner, for example, yet it is also applicable to other than the RF-AGC circuit. When applied to other than the RF-AGC circuit, amplifiers may be connected to the input stages of the second to fourth initial-stage LNAs 2 to 4 instead of the attenuators 11 to 13. That is, the above embodiment has explained the example where the dynamic range of a total of 80 [dB] is acquired by attenuating the input signal in increments of 20 [dB], but it is also possible to acquire the dynamic range of a total of 80 [dB] by amplifying the input signal in increments of 20 [dB]. In this case, the amplifiers used instead of the attenuators 11 to 13 make up the level adjuster of the present invention.

Furthermore, the above embodiment has explained the example where the inverters INV1 and INV2, PMOS transistor P6 and nMOS transistors N9 and N10 shown in FIG. 4 make up the switch means, but this is a mere example. For example, the inverters INV1 and INV2 and PMOS transistor P6 may also make up the switch means. In this case, at least it is possible to completely separate the first amplifier 50, second amplifier 60 and bias circuit N5 and N6 from the supply voltage VDD when the initial-stage control currents IB1 to IB4 are not supplied form the variable current source 20. Though the amplification operation is not performed because the initial-stage control currents IB1 to IB4 are not supplied, it is possible to suppress deterioration of the noise factor by completely separating the transistors from the supply voltage VDD in such a case.

Alternatively, the switch means may also be constructed of the nMOS transistors N9 and N10. In this case, at least the transistor N4 making up the first amplifier 50 and the transistor N3 making up the second amplifier 60 completely turn OFF because their gates become low level. Thus, when the initial-stage control currents IB1 to IB4 are not supplied from the variable current source 20, it is possible to suppress deterioration of the noise factor by completely turning OFF the operations of the first amplifier 50 and second amplifier 60.

Furthermore, the above embodiment has explained the example where signals are added up at the output stages of the pre-stage transistors in the cascode connection of two cascode amplifiers making up the next-stage LNA 5, but the present invention is not limited to this. For example, signals may also be added up at the output stages of the post-stage transistors in the cascode connection.

In addition, the above embodiment illustrates only one example of embodiment in implementing the present invention and the technical scope of the present invention should not be thereby interpreted in a limited way. That is, the present invention can be implemented in various ways without departing from the spirit or major features thereof.

### INDUSTRIAL APPLICABILITY

The present invention is useful for a variable gain amplifier with a plurality of amplifiers connected to increase the variable gain range. For example, the variable gain amplifier according to the present invention is suitable for use in a radio tuner mounted on a mobile station such as a vehicle-mounted system or a cellular phone.

What is claimed is:

1. A variable gain amplifier comprising:
a plurality of initial-stage amplifiers connected parallel to one input for performing amplification operation by initial-stage control currents which are let flow through the respective amplifiers;
level adjusters connected to input sides of the initial-stage amplifiers with respect to at least some of the plurality of initial-stage amplifiers for adjusting levels of signals inputted to the plurality of initial-stage amplifiers so as to differ from each other;
a next-stage amplifier connected after the plurality of initial-stage amplifiers for performing amplification operation by a next-stage control current, a plurality of combined output lines formed by connecting output lines of initial-stage amplifiers out of the plurality of initial-stage amplifiers through which the initial-stage control currents never flow simultaneously being connected to a plurality of input ends separately, and signals inputted from the plurality of input ends being amplified and the respective amplified signals being added up and outputted; and
a variable current source for controlling the initial-stage control currents to be let flow through the plurality of initial-stage amplifiers and the next-stage control current to be let flow through the next-stage amplifier,
wherein the variable current source performs control such that a total value of the initial-stage control currents to be let flow through the simultaneously operated initial-stage amplifiers out of the plurality of initial-stage amplifiers is kept constant and such that a next-stage control current of magnitude proportional to the initial-stage control currents to be let flow through the initial-stage amplifiers is let flow through the next-stage amplifier.

2. The variable gain amplifier according to claim 1, the plurality of initial-stage amplifiers each comprise:
a first amplifier for amplifying an input signal by inverting a phase thereof; and
a second amplifier for amplifying the input signal;
wherein an output signal of the first amplifier and an output signal of the second amplifier are added up and outputted.

3. The variable gain amplifier according to claim 2, the plurality of initial-stage amplifiers each further comprise:
switch means for turning OFF operations of the first amplifier and the second amplifier when the initial-stage control current is not supplied from the variable current source.
